(19) United States
(12) Patent Application Publication
(10) Pub. No.: US 2008/0230809 A1
(43) Pub. Date: Sep. 25, 2008

(54) Semiconductor device and method of fabricating the same

(76) Inventor: Yoshikazu Ibara, Motosu-gun (JP)

Correspondence Address: MCDERMOTT WILL & EMERY LLP, 600 13TH STREET, N.W., WASHINGTON, DC, 20005-3096, US

(21) Appl. No.: 12/073,053

(22) Filed: Feb. 28, 2008

(30) Foreign Application Priority Data
Feb. 28, 2007 (JP) JP2007-048254

(51) Int. Cl. H01L 29/737; H01L 21/331

(52) U.S. Cl. 257/198; 438/317; 257/E29.191; 257/E21.371

(57) ABSTRACT

A sophisticated semiconductor device capable of being fabricated without introducing a high-precision exposure apparatus is obtained. This semiconductor device includes a conductive layer formed on a first conductivity type collector layer, a first conductivity type emitter electrode formed on the conductive layer and a protruding portion protruding from an outer side toward an inner side of the emitter electrode along an interface between the emitter electrode and the conductive layer. The conductive layer has a first conductivity type emitter diffusion layer in contact with the emitter electrode through the protruding portion and a second conductivity type base layer.

### BACKGROUND OF THE INVENTION

1. Field of the Invention

The present invention relates to a semiconductor device and a method of fabricating the same.

2. Description of the Background Art

Recently, as portable electronic apparatuses such as a portable telephone, a personal digital assistance (PDA), a digital video camera (DVC), and a digital steel camera (DSC) have become rapidly sophisticated, downsizing and weight saving have been essential in order to accept these products in a market. In order to attain this, a high integration system LSI can be demanded.

A high-frequency bipolar transistor is an exemplary module attaining the high integration system LSI. A heterojunction bipolar transistor (semiconductor device) in which a base layer is made of a silicon germanium (SiGe) alloy is known as an exemplary structure attaining sophistication of the high-frequency bipolar transistor in general, as disclosed in Japanese Patent Laying-Open No. 2006-54409, for example.

FIG. 9 is a sectional view schematically showing a main structure of the conventional bipolar transistor disclosed in Japanese Patent Laying-Open No. 2006-54409. The structure of the bipolar transistor (semiconductor device) described in Japanese Patent Laying-Open No. 2006-54409 will be described with reference to FIG. 9.

In the conventional bipolar transistor, a collector layer 102 is formed on a p-type silicon substrate 101 as shown in FIG. 9. This collector layer 102 is formed by epitaxially growing an n-type silicon on a silicon substrate 101. An element isolation layer 103 formed by STI (shallow trench isolation) is formed on a part of the collector layer 102. A p-type SiGe alloy layer 106a is formed on the collector layer 102. The p-type silicon layer 107a having a projecting shape in cross section is formed on the SiGe alloy layer 106a, and an n-type emitter diffusion layer 113 employed as an emitter layer is formed on an upper portion of a silicon film 107a. This emitter diffusion layer 113 is formed by diffusing an n-type impurity from an after-mentioned polycrystalline silicon film 108a on the silicon film 107a having the projecting shape in cross section. The SiGe alloy layer 106a and a region in the silicon film 107a, into which no n-type impurity is diffused constitute a base layer. The polycrystalline silicon film 108a employed as an emitter electrode is formed on the emitter diffusion layer 113. A side wall film 111 (commonly referred to as a side wall) made of an insulating film is so formed as to cover side surfaces of the emitter diffusion layer 113 and the polycrystalline silicon film 108a. A contact surface 150 between the polycrystalline silicon film 108a and the emitter diffusion layer 113 is located above a lower surface 160 of the side wall film 111. A p-type outer base diffusion layer 112 employed as an outer base layer is formed on a region outside the side wall film 111.

According to such a conventional bipolar transistor, the contact surface 150 between the silicon film 107a and the polycrystalline silicon film 108a is located above the lower surface 160 of the side wall film 111, whereby the side wall film 111 can inhibit from laterally diffusing the n-type impurity when the emitter diffusion layer 113 is formed by thermally diffusing the n-type impurity from the polycrystalline silicon film 108a into the silicon film 107a having the projecting shape in cross section. Thus, a width along the contact surface 150 of the emitter layer (emitter diffusion layer 113) can be reduced.

The width along the contact surface 150 of the emitter layer is further reduced in order to fabricate a further sophisticated semiconductor device (SiGe base heterojunction bipolar transistor) in the future. In this case, a width along the contact surface 150 of the polycrystalline silicon film 108a is required to be reduced in order to reduce the width along the contact surface 150 of the emitter layer in the conventional semiconductor device. In order to reduce the width along the contact surface 150 of the polycrystalline silicon film 108a, however, a high-precision exposure apparatus is disadvantageously required to be introduced.

### SUMMARY OF THE INVENTION

An object of the present invention is to provide to a sophisticated semiconductor device capable of being fabricated without introducing a high-precision exposure apparatus and a method of fabricating the same.

A semiconductor device according to a first aspect of the present invention comprises a conductive layer formed on a first conductivity type collector layer, a first conductivity type emitter electrode formed on the conductive layer and a protruding portion protruding from an outer side toward an inner side of the emitter electrode along an interface between the emitter electrode and the conductive layer, wherein the conductive layer has a first conductivity type emitter diffusion layer in contact with the emitter electrode through the protruding portion and a second conductivity type base layer.

A method of fabricating a semiconductor device according to a second aspect of the present invention comprises steps of forming a second conductivity type conductive layer on a first conductivity type collector layer, forming an emitter electrode containing a first conductivity type impurity on the conductive layer, forming a protruding portion protruding from an outer side toward an inner side of the emitter electrode along an interface between the emitter electrode and the conductive layer and forming a first conductivity type emitter diffusion layer containing the impurity contained in the emitter electrode and a second conductivity type base layer in the conductive layer by diffusing the impurity into a surface of the conductive layer through the protruding portion.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view schematically for illustrating a bipolar transistor according to an embodiment of the present invention;

FIG. 2 is a partially enlarged view with a focus on emitter and base regions of the bipolar transistor shown in FIG. 1;

FIGS. 3 to 7 are sectional views for schematically illustrating a step of fabricating the bipolar transistor according to the embodiment of the present invention;

FIG. 8 is a partially enlarged view with a focus on emitter and base regions of a bipolar transistor according to a modification of the present invention; and

FIG. 9 is a sectional view schematically showing a main structure of a conventional bipolar transistor.

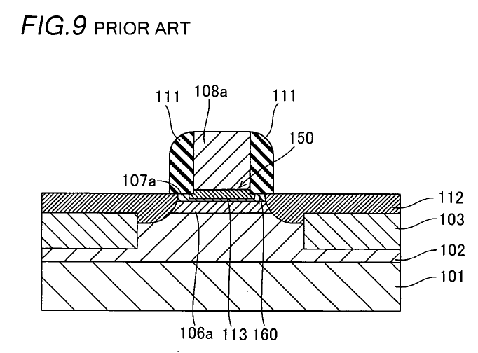

### DESCRIPTION OF THE PREFERRED EMBODIMENTS

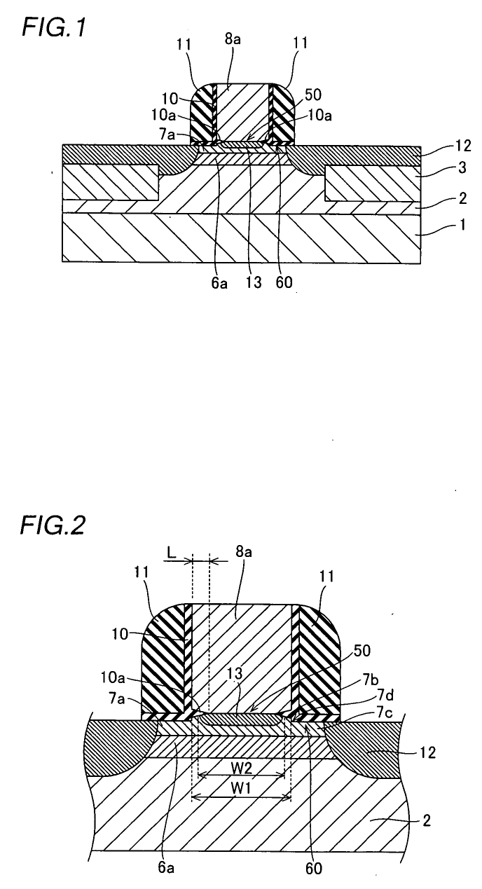

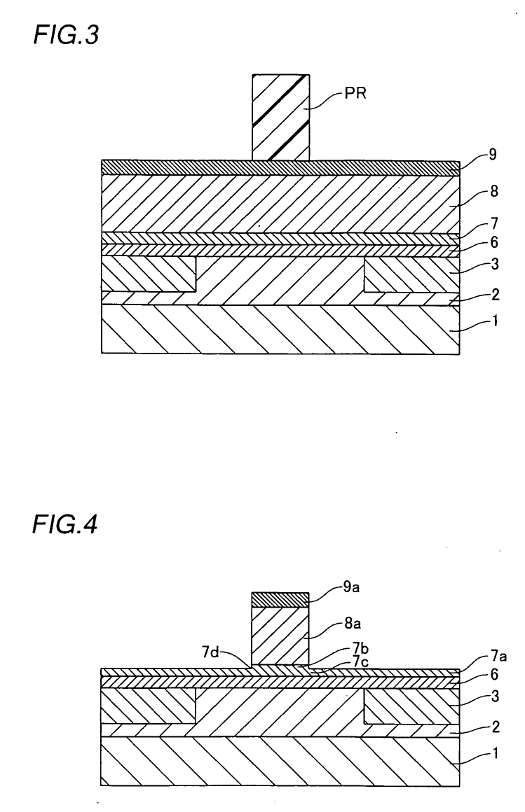

A structure of a bipolar transistor according to an embodiment of the present invention will be now described with reference to FIGS. 1 and 2.

The bipolar transistor according to this embodiment is an NPN heterojunction bipolar transistor in which a base is made of an SiGe alloy. As shown in FIGS. 1 and 2, a collector layer 2 is formed on a p-type silicon substrate 1 in this bipolar transistor. The collector layer 2 is formed by epitaxially growing n-type silicon on the silicon substrate 1. An element isolation layer 3 formed by STI is formed on a part of this collector layer 2. A region surrounded by the element isolation layer 3 is an active region among a collector layer 2.

A conductive layer formed by the p-type SiGe alloy layer 6a and the p-type silicon layer 7a having the projecting shape in cross section are formed on the active region of the collector layer 2. The band gap of the SiGe alloy layer is narrower than that of the silicon film. An n-type emitter diffusion layer 13 serving as an emitter layer is formed on an upper portion in the silicon film 7a. The SiGe alloy layer 6a and a region in the silicon film 7a, into which no n-type impurity is diffused constitute the base layer. An n-type polycrystalline silicon film 8a is formed on the emitter diffusion layer 13. The silicon film 7a includes an upper portion 7b having a width identical with that of the polycrystalline silicon film 8a and a lower portion 7c having a width lager than that of the polycrystalline silicon film 8a. The upper portion 7b and the lower portion 7c form a step 7d. The polycrystalline silicon film 8a is an example of the “emitter electrode” in the present invention. The SiGe alloy layer 6a is an example of the “narrow band gap region” in the present invention.

According to this embodiment, an insulating film 10 is formed on side surfaces of the polycrystalline silicon film 8a and a surface of the silicon film 7a. A protruding portion 10a (protruding amount L) made of a silicon oxide film protruding from an outer side toward an inner side of the polycrystalline silicon film 8a is circumferentially formed along an interface 50 between the polycrystalline silicon film 8a and the silicon film 7a. The insulating film 10 is formed integrally with the protruding portion 10a. The interface 50 between the silicon film 7a and the polycrystalline silicon film 8a is located above a lower surface 60 (step 7d between a first portion 7b and a second portion 7c of the silicon film 7a) of the insulating film 10. Thus, a width W2 along the interface 50 of the emitter diffusion layer 13 (emitter layer) in the silicon film 7a is smaller than a width W1 (width W1 along the interface 50 of the first portion 7b of the silicon film 7a) along the interface 50 of the polycrystalline silicon film 8a.

A side wall film 11 made of an insulating film is so formed as to cover a surface of the insulating film 10. A region outside the side wall film 11 is formed with a p-type outer base diffusion layer 12 employed as an outer base layer.

A process of fabricating the bipolar transistor according to this embodiment will be described with reference to FIGS. 1 to 7.

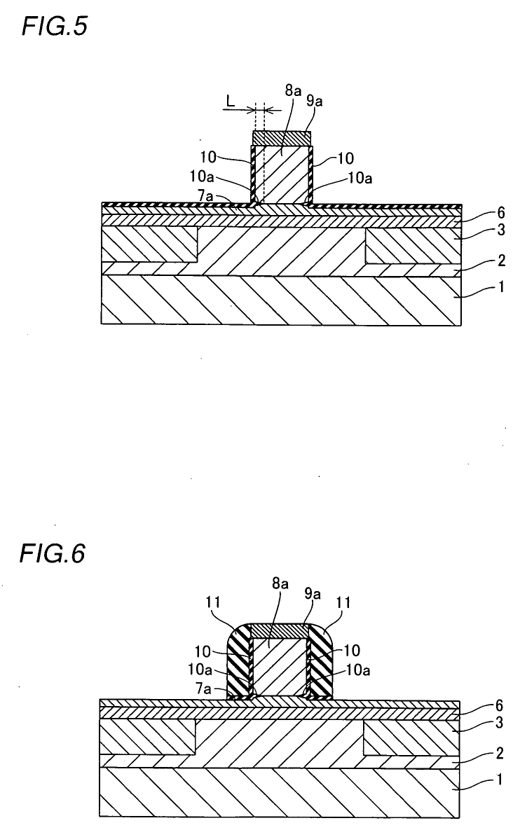

As shown in FIG. 3, an epitaxial layer as the collector layer 2 is formed by epitaxially growing n-type silicon on the p-type silicon substrate 1 by commonly known technique. Then the element isolation layer 3 formed by STI is formed on a part of the collector layer 2. An element isolation layer of an insulating film formed by LOCOS (local oxidation of silicon) may be employed in place of the element isolation layer 3 formed by STI. A SiGe alloy layer 6 doped with a p-type impurity and a silicon film 7 containing no germanium (Ge) are epitaxially grown by low pressure CVD (chemical vapor deposition). Thereafter a polycrystalline silicon film 8 doped with a high-concentration n-type impurity is stacked by low pressure CVD. A silicon nitride film 9 is stacked on the polycrystalline silicon film 8. A resist mask PR having a prescribed pattern is formed for processing the polycrystalline silicon film 8 into a desired emitter electrode by lithography.

As shown in FIG. 4, the silicon nitride film 9 is processed as a silicon nitride film 9a by dry etching. The silicon nitride film 9a serves as a mask for processing the polycrystalline silicon film 8 by etching. Then the polycrystalline silicon film 8 and the silicon film 7 are successively dry etched. At this time, dry etching is not performed until the silicon film 7 is completely removed, and is completed in a state where a part of the silicon film 7 remains on an overall surface of the SiGe alloy layer 6. Consequently, the silicon film 7a having the projecting shape in cross section, constituted by the first portion 7b, the second portion 7c and the step 7d is formed. At this time, etching damage is caused on the surface of the silicon film 7a, thereby forming a damage layer (not shown). The polycrystalline silicon film 8 is processed as the polycrystalline silicon film 8a serving as an emitter electrode.

As shown in FIG. 5, the side surfaces of the polycrystalline silicon film 8a and the surface of the silicon film 7a are thermally oxidized by thermal oxidation, thereby forming the insulating film 10 made of the silicon oxide film. The insulating film 10 is formed while the protruding portion 10a (protruding amount L) made of the silicon oxide film protruding from the outer side toward the inner side of the polycrystalline silicon film 8a is simultaneously formed along the interface 50 between the polycrystalline silicon film 8a and the silicon film 7a. The thermal oxidation is performed at about 900° C. for about 10 seconds in an O₂ atmosphere with an existing RTO (rapid thermal oxidation) device, for example. Thus, a thermal oxide film having a thickness of 5 to 15 nm is formed on the side surfaces of the polycrystalline silicon film 8a and the surface of the silicon film 7a as the insulating film 10. The bird's beak shaped protruding portion 10a made of the silicon oxide film having the protruding amount L of about 1 to 5 nm from the outer side of the polycrystalline silicon film 8a is formed along the interface 50 between the polycrystalline silicon film 8a and the silicon film 7. The n-type impurity in the polycrystalline silicon film 8a hardly diffuses into the silicon film 7a under the aforementioned condition of the RTO.

As shown in FIG. 6, the silicon oxide film is stacked on the overall surface by CVD and the overall surface is etched back by dry etching. Thus, the side wall film 11 made of the silicon oxide film referred to as a side wall is so formed as to cover the side surfaces of the silicon nitride film 9a and the insulating film 10. At this time, unnecessary portion of the insulating film 10 as the thermal oxide film formed on the surface of the silicon film 7a is removed. As shown in FIG. 7, the silicon nitride film 9a and the side wall film 11 are employed as masks for implanting the p-type impurity by ion-implantation and thereafter activated by thermal treatment. Thus, the p-type outer base diffusion layer 12 serving as the outer base layer is formed on the region outside the side wall film 11. A region in the SiGe alloy layer 6, into which no p-type impurity is implanted becomes the SiGe alloy layer 6a. The condition of this ion implantation is that ions do not pass through the silicon nitride film 9a existing on the polycrystalline silicon film 8a, whereby it is possible not to implant the p-type impurity into the polycrystalline silicon film 8a.

As shown in FIG. 1, the n-type impurity in the polycrystalline silicon film 8a is diffused into the silicon film 7a by thermal treatment. Thus, the n-type emitter diffusion layer 13 serving as the emitter layer is formed. Consequently, a region where the n-type impurity (emitter diffusion layer 13) is contained and a region where no n-type impurity is contained are formed in the silicon film 7a and an emitter-base junction is formed in the silicon film 7a. The thermal treatment is performed at about 1050° C. for about 5 to 30 seconds with a RTA (rapid thermal anneal) device.

According to this embodiment, the protruding portion 10a formed along the interface 50 becomes a diffusion barrier of the n-type impurity when the emitter diffusion layer 13 is formed by diffusing the n-type impurity from the polycrystalline silicon film 8a, whereby diffusion of the n-type impurity into the silicon film 7a is restricted. Thus, a width of the portion contributing to formation of the emitter diffusion layer 13 in the polycrystalline silicon film 8a can be reduced by the protruding amount of the protruding portion 10a.

The etching damage (damage layer) caused on the surface (side surfaces of the first portion 7b and the upper surface of the second portion 7c (see FIG. 2)) of the silicon film 7a having the projecting shape in cross section remains also after forming the side wall film 11. The rate of solid-phase diffusion of the n-type impurity is increased in such a damage layer at the time of thermal diffusion. Therefore, the thickness of the emitter layer is nonuniform due to wide diffusion of the n-type impurity in the damage layer when the n-type impurity is diffused into the damage layer, as in a case of a conventional structure (case where no protruding portion exist). With this, a withstand voltage is reduced since the thickness of the base layer is relatively thin at a portion of the damage layer, and hence a prescribed transistor operation may not be obtained. On the other hand, in the case where the protruding portion 10a is provided along the interface 50, the protruding amount L of the protruding portion 10a is adjust so as to cover the damage layer, whereby diffusion of the n-type impurity into the damage layer can be suppressed.

A salicide electrode (not shown) is formed after removing the silicon nitride film 9a. An insulating film is stacked on a surface of a semiconductor substrate, although not shown. Openings for contact are formed on regions corresponding to the collector layer, the outer base layer and the emitter electrode of the insulating film respectively. Thereafter plugs connected to the collector layer, the outer base layer and the emitter electrode through the openings of the regions respectively are formed, thereby fabricating the bipolar transistor (semiconductor device) according to this embodiment.

According to this embodiment, as hereinabove described, the protruding portion 10a protruding from the outer side toward the inner side of the emitter electrode (polycrystalline silicon film 8a) is formed, whereby the impurity can be inhibited from diffusing into the portion of the silicon film 7a corresponding to the portion where the protruding portion 10a is formed when diffusing the impurity from the emitter electrode to the silicon film 7a. Therefore, the width W2 along the interface 50 of the emitter diffusion layer 13 can be reduced by the protruding length L of the protruding portion 10a. Thus, the width along the interface 50 of the emitter diffusion layer 13 can be reduced without reducing the width of the emitter electrode (polycrystalline silicon film 8a) by introducing the high-precision exposure apparatus. Therefore, the sophisticated bipolar transistor can be fabricated without introducing the high-precision exposure apparatus.

According to this embodiment, as hereinabove described, the protruding portion 10a is formed, whereby the protruding portion 10a can suppress diffusion of the n-type impurity into the damage layer. Thus, variation in the thickness or the width of the emitter layer (emitter diffusion layer 13) can be reduced, and hence a bipolar transistor having a small variation in performance can be obtained.

According to this embodiment, as hereinabove described, the width W2 along the interface 50 of the emitter layer (emitter diffusion layer 13) is smaller than the width W1 along the interface 50 of the emitter electrode (polycrystalline silicon film 8a), whereby the same current density can be obtained with a small amount of a current as compared with a conventional case, and a high current amplification factor can be obtained. Thus, a bipolar transistor having low consumption power can be obtained.

According to this embodiment, as hereinabove described, the protruding portion 10a is formed on the interface 50 by thermal treatment employing the existing thermal treatment device, whereby the width of the portion contributing to the formation of the emitter diffusion layer 13 in the polycrystalline silicon film 8a can be reduced without introducing the high-precision exposure apparatus. Thus, the bipolar transistor in which the width W2 along the interface 50 of the emitter layer (emitter diffusion layer 13) is small can be fabricated at a low cost.

According to this embodiment, as hereinabove described, the protruding portion 10a is formed by growing the oxide film along the interface 50 by thermal treatment, whereby the process is stabilized and the width of the portion contributing to the formation of the emitter diffusion layer 13 in the polycrystalline silicon film 8a can be easily reduced.

Although the present invention has been described and illustrated in detail, it is clearly understood that the same is by way of illustration and example only and is not to be taken by way of limitation, the spirit and scope of the present invention being limited only by the terms of the appended claims.

For example, while the present invention is applied to the NPN bipolar transistor in the aforementioned embodiment, the present invention is not restricted to this but also applicable to a PNP bipolar transistor in which conductive types of the respective regions are reversed.

While the collector layer 2 is formed by staking the epitaxial layer made of silicon on the silicon substrate 1 in the aforementioned embodiment, the present invention is not restricted to this but the collector layer may be formed by ion-implanting a p-type or n-type impurity from a surface of a silicon substrate 1 reversed in polarity from the impurity.

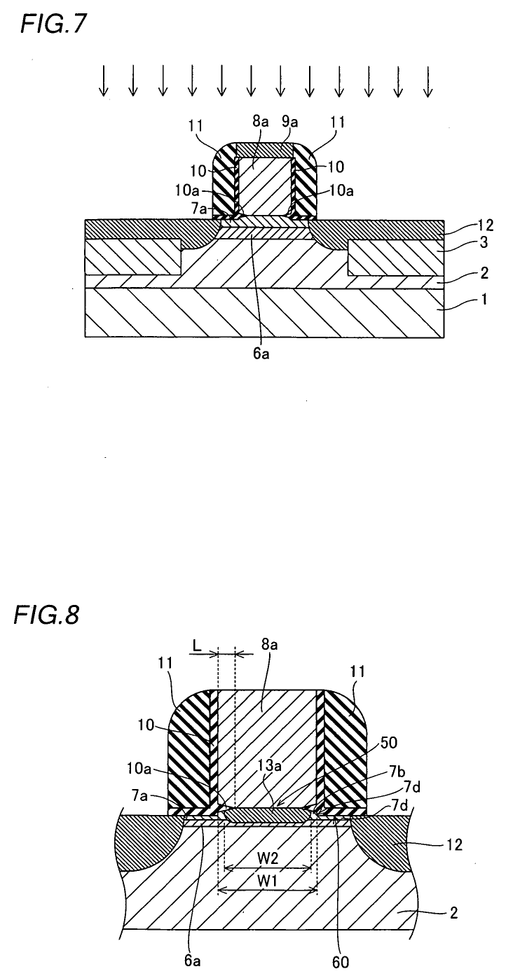

While the lower surface of the emitter diffusion layer 13 employed as the emitter layer is located in the silicon film 7a in the aforementioned embodiment, the present invention is not restricted to this. For example, a lower surface of an emitter diffusion layer 13a reaches into a SiGe alloy layer 6a by reducing the thickness of a silicon film 7a as in a semiconductor device according to a modification as shown in FIG. 8. According to this structure, a distance from the lower surface of the emitter diffusion layer 13a to an active region (collector layer 2) can be reduced as compared with the aforementioned embodiment (case where the lower surface of the emitter diffusion layer 13a does not reach into the SiGe alloy layer 6a). Thus, a transit time of electrons flowing from the emitter layer to the collector layer can be reduced and hence a transistor operating at a high speed can be formed.

In the case where the lower surface of the emitter diffusion layer 13a is in the SiGe alloy layer 6a, the band gap of the SiGe alloy layer is narrower than that of the silicon film and hence the height of a barrier with respect to electrons injected from the emitter layer (emitter diffusion layer 13a) to the base layer (SiGe alloy layer 6a) is reduced. Thus, an emitter injection efficiency is increased and hence a higher current amplification factor can be obtained.

What is claimed is:

1. A semiconductor device comprising:
a conductive layer formed on a first conductivity type collector layer;
a first conductivity type emitter electrode formed on said conductive layer; and
a protruding portion protruding from an outer side toward an inner side of said emitter electrode along an interface between said emitter electrode and said conductive layer, wherein
said conductive layer has a first conductivity type emitter diffusion layer in contact with said emitter electrode through said protruding portion and a second conductivity type base layer.

2. The semiconductor device according to claim 1, wherein
said protruding portion is made of an insulator.

3. The semiconductor device according to claim 2, wherein
said protruding portion is made of a silicon oxide film.

4. The semiconductor device according to claim 1, wherein
said protruding portion is circumferentially formed so as to protrude from the outer side toward the inner side of said emitter electrode.

5. The semiconductor device according to claim 1, further comprising an insulating film formed so as to cover at least side surfaces of said emitter electrode, wherein
said protruding portion is formed integrally with said insulating film.

6. The semiconductor device according to claim 5, further comprising a side wall insulating film covering side surfaces of said insulating film.

7. The semiconductor device according to claim 5, wherein
said interface is located above a lower surface of said insulating film.

8. The semiconductor device according to claim 5, wherein
said conductive layer includes:
a first portion arranged closer to said emitter electrode and having a width along said interface substantially equal to that of said emitter electrode, and
a second portion arranged closer to said collector layer and having a width along said interface larger than that of said emitter electrode, wherein
said insulating film is so formed as to cover a step portion between said first portion and said second portion.

9. The semiconductor device according to claim 8, wherein
said protruding portion is formed on a side closer to said emitter electrode than said step portion between said first portion and said second portion.

10. The semiconductor device according to claim 1, wherein
a width along said interface of said emitter diffusion layer is smaller than a width along said interface of said emitter electrode.

11. The semiconductor device according to claim 1, wherein
said base layer includes a narrow band gap region made of a material having a band gap narrower than that of said emitter electrode.

12. The semiconductor device according to claim 11, wherein
said narrow band gap region is in contact with said emitter diffusion layer.

13. A method of fabricating a semiconductor device, comprising steps of:
forming a second conductivity type conductive layer on a first conductivity type collector layer;
forming an emitter electrode containing a first conductivity type impurity on said conductive layer;
forming a protruding portion protruding from an outer side toward an inner side of said emitter electrode along an interface between said emitter electrode and said conductive layer; and
forming a first conductivity type emitter diffusion layer containing said impurity contained in said emitter electrode and a second conductivity type base layer in said conductive layer by diffusing said impurity into a surface of said conductive layer through said protruding portion.

14. The method of fabricating a semiconductor device according to claim 13, wherein
said step of forming said protruding portion includes a step of forming said protruding portion by thermally oxidizing the vicinity of the interface between said emitter electrode and said conductive layer.

15. The method of fabricating a semiconductor device according to claim 14, wherein
said protruding portion is made of a silicon oxide film.

16. The method of fabricating a semiconductor device according to claim 14, wherein
said step of forming said protruding portion includes a step of simultaneously forming said protruding portion and an insulating film covering at least side surfaces of said emitter electrode by thermal oxidation.

17. The method of fabricating a semiconductor device according to claim 16, further comprising a step of forming a side wall insulating film covering side surfaces of said insulating film.

18. The method of fabricating a semiconductor device according to claim 13, wherein
said step of forming said conductive layer includes a step of forming a first portion arranged closer to said emitter electrode and having a width along said interface substantially equal to that of said emitter electrode and a second portion arranged closer to said collector layer and having a width along said interface larger than that of said emitter electrode by etching.

19. The method of fabricating a semiconductor device according to claim 13, wherein
said base layer includes a narrow band gap region made of a material having a band gap narrower than that of said emitter electrode.

20. The method of fabricating a semiconductor device according to claim 19, wherein
said narrow band gap region is in contact with said emitter diffusion layer.
